(19) United States
(12) Patent Application Publication
(10) Pub. No.: US 2005/0286229 A1
(43) Pub. Date: Dec. 29, 2005

(54) Modular heat-dissipation assembly structure for a PCB

(75) Inventor: Shih-Chang Ku, Hsin Tien City (TW)

Correspondence Address: BIRCH STEWART KOLASCH & BIRCH, PO BOX 747, FALLS CHURCH, VA, 22040-0747, US

(73) Assignee: VIA TECHNOLOGIES, INC.

(21) Appl. No.: 11/073,673

(22) Filed: Mar. 8, 2005

(30) Foreign Application Priority Data
Jun. 23, 2004 (TW) 93209864

(51) Int. Cl. H05K 7/20

(52) U.S. Cl. 361/709

(57) ABSTRACT

A modular heat-dissipation assembly structure for a PCB is described. The structure is formed in a modular way on a peripheral enclosure to meet the thermal budget of the PCB, and has a modular enclosure, a PCB, and at least one heat pipe. The modular enclosure has a plurality of boards and at least one assembly opening. One of the boards has a plurality of fins extending outwardly to form a heat-dissipation board. The PCB is assembled in the modular enclosure, and has at least one processing chip. The at least one heat pipe connects the processing chip to the heat-dissipation board.

### BACKGROUND OF THE INVENTION

1. Field of the Invention

The present invention relates to a modular heat-dissipation assembly structure for a PCB, which integrates the thermal budget of a PCB into a module, particularly to extend the heat-dissipation solution of the PCB to the surrounding casing and dissipate heat to the atmospheric environment directly.

2. Description of Related Art

FIG. 1 is a schematic, perspective view of a PCB and a heat sink according to the prior art. To provide heat-dissipation for electronic elements 72 (such as CPU, South Bridge chip, or North Bridge chip) on a PCB 7 in the conventional art, a heatsink 74 usually is assembled on the electronic elements 72 and a fan 76 is further assembled on the heat sink 74. All the mentioned elements are installed in a housing 8, after completing the design of the electronic elements 72. Therefore, different heat sinks are assembled on the electronic elements 72 according to the thermal budget. However, semiconductor integrated circuits are developing quickly, and more and more new heat sinks are designed continually to deal with the increasing thermal budget. Moreover, different fixing devices and assembly technologies for the new heat sinks must be developed.

Overall, the conventional heat-dissipating system of the PCB has disadvantages described as follows:
1. The housing type and the operation environment, such as, for example, the boundary conditions of fluid field, temperature and pressure distribution, of the electronic elements (for example, a processing chip) cannot be defined beforehand, so a universal heat sink cannot be provided.
2. Element suppliers cannot provide an effective heat-dissipation design to the downstream manufactories. PCB suppliers also cannot provide an effective heat-dissipation design to the downstream manufactories.
3. Because the elements and the heat-dissipation device are surrounded by the housing and the heat-dissipation is limited by the housing, the temperature around the electronic elements and the heat-dissipation device is higher than that of the atmospheric environment by 5 to 20 degrees centigrade. The substantially increased thermal budget leads to a bulky heat-dissipation device, and the total size is increased. The heavy total weight also results in a warped PCB and influences the operation of the other electronic elements. In extreme cases, the thermal budget cannot be met and the system design fails.

### SUMMARY OF THE INVENTION

An object of the present invention is to provide a modular heat-dissipation assembly structure for a PCB that integrates all the thermal budgets of electronic elements on a PCB in a modular heat-dissipation element, which modular heat-dissipation element can dissipate heat to the atmospheric environment and thus substantially lower the surrounding temperature of the electronic elements.

Another object of the present invention is to provide a modular heat-dissipation assembly structure for a PCB to loosen the thermal budget of a PCB heat-dissipation solution, thereby allowing provision of a lightweight system.

In order to achieve the above objects, the present invention provides a modular heat-dissipation assembly structure for a PCB comprising a modular enclosure, a PCB, and at least one heat pipe. The modular enclosure has a plurality of boards and at least one assembly opening. At least one of the boards has a plurality of fins extending outwardly and forming a heat-dissipation board. The PCB is assembled in the modular enclosure and has at least one processing chip. The at least one heat pipe connects the processing chip with the heat-dissipation board.

### BRIEF DESCRIPTION OF THE DRAWINGS

The invention will be better understood and objects other than those set forth above will become apparent when consideration is given to the following detailed description thereof. Such description makes reference to the annexed drawings, wherein:

FIG. 1 is a schematic, perspective view of a PCB and a heat sink according to the prior art;

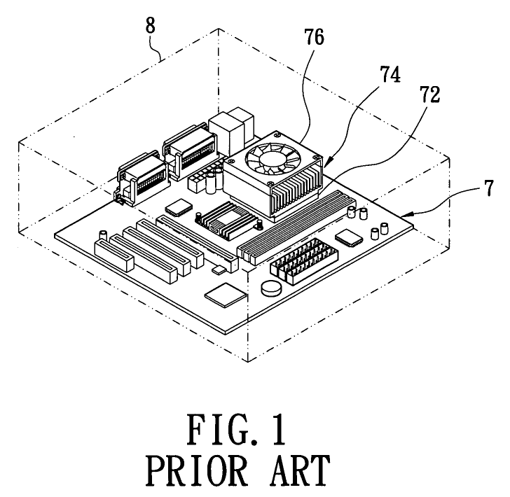

FIG. 2 is a schematic, perspective, exploded view of a modular heat-dissipation assembly structure for a PCB according to the present invention;

FIG. 3 is a schematic, perspective, exploded view of a modular heat-dissipation assembly structure for a PCB of another embodiment according to the present invention;

FIG. 4 is a schematic, perspective, exploded view of a modular heat-dissipation assembly structure for a PCB applied on a personal PC according to the present invention; and

FIG. 5 is a schematic, perspective, assembled view of a modular heat-dissipation assembly structure for a PCB according to the present invention applied in a PC.

### DETAILED DESCRIPTION OF PREFERRED EMBODIMENTS

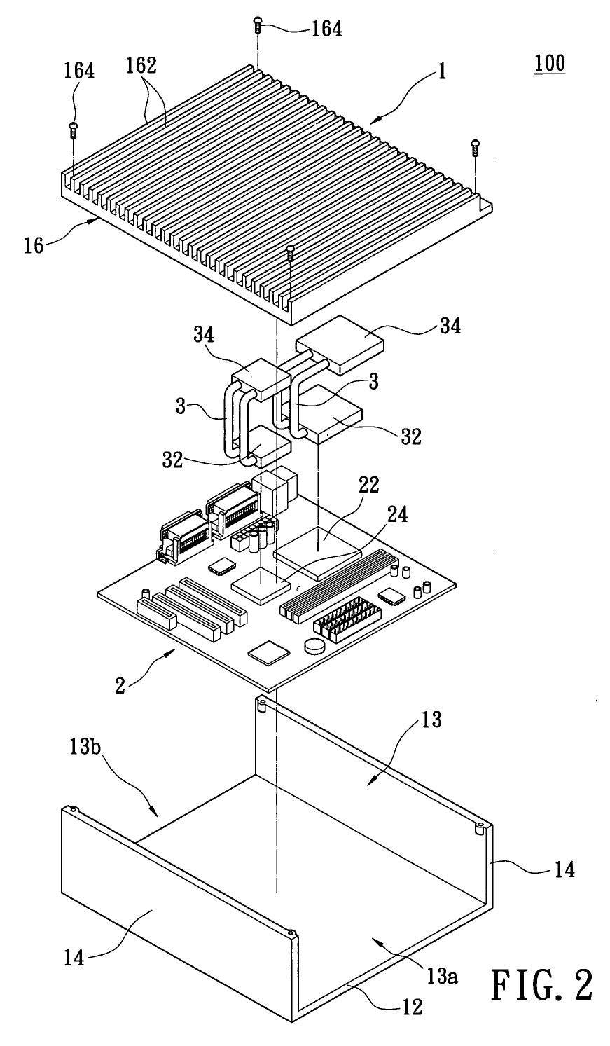

FIG. 2 is a schematic, perspective, exploded view of a modular heat-dissipation assembly structure for a PCB according to the present invention. The modular heat-dissipation assembly structure for a PCB 100 comprises a modular enclosure 1, a PCB 2, and at least one heat pipe 3.

The modular enclosure 1 has a plurality of boards 12, 14, 16 and at least one assembly opening 13 for assembling the PCB 2. At least one of the boards, in this embodiment, the board 16, has a plurality of fins 162 extending outwardly and forming a heat-dissipation board 16. The heat-dissipation board 16 is exposed to the atmospheric environment and has a large heat-dissipation area. In this embodiment, the modular enclosure 1 has U-shaped board composed of a bottom board 12 and two sideboards 14 by bending. The U-shaped board defines the assembly opening 13 and two side assembly openings 13a, 13b. The heat-dissipation board 16 is fixed to the U-shaped board by screws 164, so that it is easy to assemble and examine the PCB 2.

The preferred manufacturing method of the heat-dissipation board 16 is aluminum extrusion. The position of the heat-dissipation board 16 is parallel to the PCB 2 and is disposed above the PCB 2, or is perpendicular to the PCB 2. A plurality of fins can further extend from the side board 14 as a heat-dissipation board.

The PCB 2 is assembled in the modular enclosure 1; for example, PCB 2 is assembled on the bottom board 12. Because the present invention has a greater heat-dissipation area then the prior art, it is adapted for a higher power chip. The type of the PCB 2 is not limited, and can be, for example a small PCB or a common PCB for a personal computer. The PCB 2 usually has at least one processing chip 22, and sometime an assistant processing chip, 24 (for South Bridge, North Bridge).

The at least one heat pipe 3 connects the processing chips 22, 24 with the heat-dissipation board 16, respectively. For enlarging the heat-dissipation area and rate, two ends of the heat pipe 3 are connected with a contact plate 32, 34, respectively, and the two contact plates 32, 34 are in contact with the processing chips 22, 24 and the heat-dissipation board 16, respectively.

The modular heat-dissipation assembly structure for a PCB 100 of the present invention integrates the thermal budget of the PCB 2 into a modular housing with heat-dissipation function. Because the heat-dissipating portion is extended to the modular housing, a universal component-level housing of fan-less solution can be defined beforehand after defining the boundary conditions of fluid field, temperature and pressure distribution. A board-level housing of fan-less solution, which can satisfy all thermal PCB budgets, is also possible.

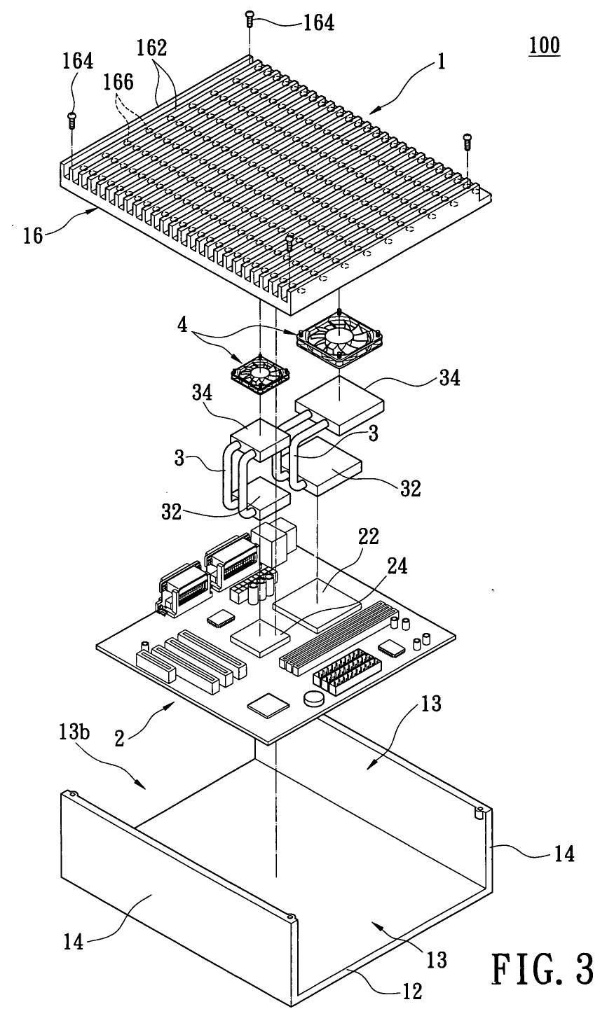

FIG. 3 is a schematic, perspective, exploded view of a modular heat-dissipation assembly structure for a PCB of another embodiment according to the present invention. The present invention can further include assembly of a fan 4 to accelerate the rate of heat dissipation. In this embodiment, the heat-dissipation board 16 is further formed with a plurality of through holes 166 on a bottom thereof for dissipating heat. At least one fan 4 is adjacent to the heat-dissipation board 16; for example a fan 4 is fixed on the bottom surface of the heat-dissipation board 16 or on the side board 14, enhancing the heat dissipation capacity of the structure.

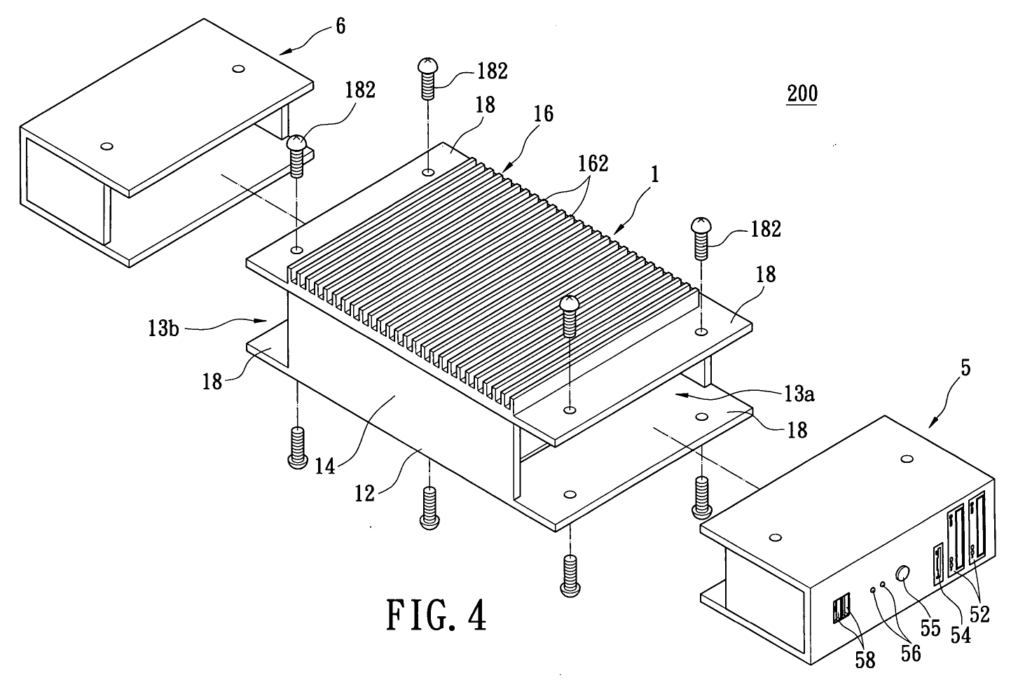

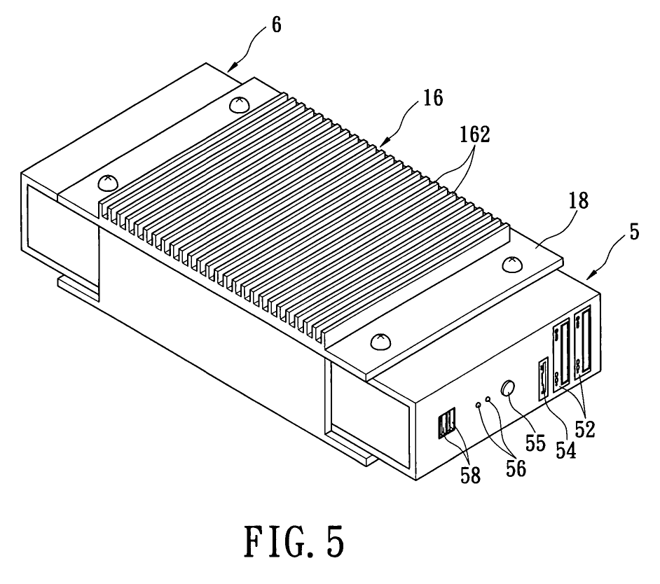

FIGS. 4 and 5 are a schematic, perspective, exploded view and a schematic, assembled view of a modular heat-dissipation assembly structure for a PCB applied on a personal PC according to the present invention. The present invention can be assembled with a PC (personal computer) 200. The heat-dissipation board 16 and the bottom board 12 include an extended assembly portion 18, respectively. A pair of side casings 5, 6 are connected to the assembly portions 18 by screws 182 for covering the assembly openings 13a, 13b. The side casing 5 is assembled with at least one peripheral element of a PC, for example a data-recess device 52 (such as a CD-ROM drive, or a disc machine), a card reader 54, a power button 55, an indicate light 56, or a connecter (such as an USB, 1394-type, or earphone plug). The connecters are electrically connected with the PCB. A plurality of connectors as external interfaces can also be assembled on the other side casing 6.

Application of the present invention is not limited to personal computers, and the present invention can be applied to PCBs with thermal budgets and the housings thereof, such as, for example, a computerized electronic system or device.

A summary of the characteristics and advantages of the modular heat-dissipation assembly structure for a PCB is as follows:

The present invention extends the heat-dissipation solution of the PCB to the surrounding casing and dissipates heat to the atmospheric environment directly. The atmospheric temperature is equal to the air temperature surrounding the heat-dissipation structure, so that it does not need to bear additional temperature (5 to 20 degrees centigrade) as in the prior art. The total weight and size can reduced anticipatively and logically.

Although the present invention has been described with reference to the preferred embodiments thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the appended claims.

1. A modular heat-dissipation assembly structure for a PCB, comprising:
a modular enclosure, having a plurality of boards and at least one assembly opening, wherein at least one of the boards has a plurality of fins extending outwardly and forming a heat-dissipation board;
a PCB, assembled in the modular enclosure and having at least one processing chip; and
at least one heat pipe, connecting the processing chip with the heat-dissipation board.

2. The modular heat-dissipation assembly structure for a PCB as in claim 1, wherein the modular enclosure has a U-shaped board, and the dissipation board is fixed with the U-shaped board; and wherein the modular enclosure has a pair of assembly openings defined on two sides thereof, and a pair of side casings fixed to the assembly openings, respectively.

3. The modular heat-dissipation assembly structure for a PCB as in claim 1, wherein the heat-dissipation board is made of aluminum by extrusion; and wherein the heat-dissipation board is further formed with a plurality of through holes for dissipating heat.

4. The modular heat-dissipation assembly structure for a PCB as in claim 1, wherein the heat-dissipation board is parallel or perpendicular to the PCB.

5. The modular heat-dissipation assembly structure for a PCB as in claim 1, wherein two ends of the heat pipe are connected with a contact plate, respectively, and the two contact plates are in contact with the processing chip and the heat-dissipation board, respectively.

6. The modular heat-dissipation assembly structure for a PCB as in claim 1, wherein the modular enclosure further comprises at least one side casing fixed to the assembly opening; and wherein the side casing includes at least one peripheral element of an electronic system assembled thereon.

7. The modular heat-dissipation assembly structure for a PCB as in claim 1, further comprising a fan adjacent to the heat-dissipation board.

8. A modular enclosure, providing a predetermined thermal budget corresponding to a PCB to form a modular heat-dissipation assembly structure, comprising:
a plurality of boards, wherein at least one board has a plurality of fins extending outwardly to form a heat-dissipation board; and
at least assembly opening formed in one side thereof.

9. The modular enclosure as in claim 8, wherein the modular enclosure has a U-shaped board, and the heat-dissipation board is fixed to the U-shaped board; and wherein the modular enclosure has a pair of assembly openings defined on two sides thereof, and a pair of side casings fixed to the assembly openings, respectively.

10. The modular enclosure as in claim 8, wherein the modular enclosure further comprises at least one heat pipe connected to a bottom surface thereof and a surface of a processing chip of the PCB.

11. The modular enclosure as in claim 10, wherein the two ends of the heat pipe are in contact with the processing chip and the heat-dissipation board.

12. The modular enclosure as in claim 8, wherein the heat-dissipation board is made of aluminum by extrusion; and wherein the heat-dissipation board is further formed with a plurality of through holes for dissipating heat.

13. The modular enclosure as in claim 8, wherein the heat-dissipation board is parallel or perpendicular to the PCB.

14. The modular enclosure as in claim 8, further comprising at least one side casing fixed to the assembly opening; and wherein at least one peripheral element of an electronic system is assembled on the side casing.

15. The modular enclosure as in claim 8, further comprising a fan adjacent to the heat-dissipation board.

16. An electronic system with a modular heat-dissipation assembly structure, comprising:
a modular enclosure, having a plurality of boards and at least one assembly opening, wherein at least one of the boards includes a plurality of fins extending outwardly and forming a heat-dissipation board;
a PCB, assembled in the modular enclosure and having at least one processing chip;
at least one heat pipe, connecting the processing chip to the heat-dissipation board;
at least one side casing fixed to the assembly opening; and
at least one peripheral element assembled on the side casing.

17. The electronic system with a modular heat-dissipation assembly structure as in claim 16, wherein the modular enclosure has a U-shaped board, and the dissipation board is fixed with the U-shaped board; and wherein the modular enclosure has a pair of assembly openings at two sides thereof, and a pair of side casings fixed to the assembly openings, respectively.

18. The electronic system with a modular heat-dissipation assembly structure as in claim 16, wherein the heat-dissipation board is made of aluminum by extrusion and wherein the heat-dissipation board is further formed with a plurality of through holes for dissipating heat.

19. The electronic system with a modular heat-dissipation assembly structure as in claim 16, wherein the heat-dissipation board is parallel or perpendicular to the PCB.

20. The electronic system with a modular heat-dissipation assembly structure as in claim 16, wherein two ends of the heat pipe are connected to a contact plate, respectively, and the two contact plates are in contact with the processing chip and the heat-dissipation board, respectively.

21. The electronic system with a modular heat-dissipation assembly structure as in claim 16, wherein at least one connecter is assembled on the side casing, and the connecter is electrically connected to the PCB.

22. The electronic system with a modular heat-dissipation assembly structure as in claim 16, further comprising a fan adjacent to the heat-dissipation board.
